(19) United States
(12) Patent Application Publication
(10) Pub. No.: US 2005/0202660 A1
(43) Pub. Date: Sep. 15, 2005

(54) Electrochemical fabrication process including process monitoring, making corrective action decisions, and taking appropriate actions

(75) Inventors: Adam L. Cohen, Los Angeles, CA (US); Michael S. Lockard, Lake Elizabeth, CA (US); Dennis R. Smalley, Newhall, CA (US); Marvin M. Kilgo III, Oakland, CA (US)

Correspondence Address: MICROFABRICA INC.;DENNIS R. SMALLEY, 1103 W. ISABEL ST., BURBANK, CA, 91506, US

(73) Assignee: Microfabrica Inc.

(21) Appl. No.: 10/995,609

(22) Filed: Nov. 22, 2004

Related U.S. Application Data
(63) Continuation-in-part of application No. 10/434,494, filed on May 7, 2003.
(63) Continuation-in-part of application No. 10/434,519, filed on May 7, 2003.
(60) Provisional application No. 60/379,132, filed on May 7, 2002.
(60) Provisional application No. 60/379,130, filed on May 7, 2002.

(51) Int. Cl. H01L 21/425

(52) U.S. Cl. 438/533

(57) ABSTRACT

Electrochemical fabrication processes and apparatus for producing multi-layer structures include operations or means for providing enhanced monitoring of build operations or detection of the results of build operations, operations or means for build problem recognition, operations or means for evaluation of corrective action options, operations or means for making corrective action decisions, and operations or means for executing actions based on those decisions.

### RELATED APPLICATIONS

This application claims benefit of U.S. Provisional Patent Application No. 60/523,951, filed Nov. 20, 2003, and is a continuation-in-part of U.S. patent application Ser. Nos. 10/434,494, and 10/434,519, both filed on May 7, 2003. Application Ser. No. 10/434,494 claims benefit of U.S. Provisional Patent Application No. 60/379,132, filed on May 8, 2002 and application Ser. No. 10/434,519 claims benefit of U.S. Provisional Patent Application No. 60/379,130, filed on May 8, 2002. All of these applications are incorporated herein in their entireties as if set forth in full.

### FIELD OF THE INVENTION

Embodiments of this invention relate to the field of electrochemical fabrication and the associated formation of multi-layer three-dimensional structures and more specifically to processes that are monitored, failures detected, and corrective actions taken. Some build processes may involve the monitoring, build problem recognition, evaluation of corrective action options, making corrective action decisions, and executing actions based on those decisions.

### BACKGROUND

A technique for forming three-dimensional structures (e.g. parts, components, devices, and the like) from a plurality of adhered layers was invented by Adam L. Cohen and is known as Electrochemical Fabrication. It is being commercially pursued by Microfabrica Inc. of Burbank, Calif. under the name EFAB™. This technique was described in U.S. Pat. No. 6,027,630, issued on Feb. 22, 2000. This electrochemical deposition technique allows the selective deposition of a material using a unique masking technique that involves the use of a mask that includes patterned conformable material on a support structure that is independent of the substrate onto which plating will occur. When desiring to perform an electrodeposition using the mask, the conformable portion of the mask is brought into contact with a substrate while in the presence of a plating solution such that the contact of the conformable portion of the mask to the substrate inhibits deposition at selected locations. For convenience, these masks might be generically called conformable contact masks; the masking technique may be generically called a conformable contact mask plating process. More specifically, in the terminology of Microfabrica Inc. of Burbank, Calif. such masks have come to be known as INSTANT MASKS™ and the process known as INSTANT MASKING™ or INSTANT MASK™ plating. Selective depositions using conformable contact mask plating may be used to form single layers of material or may be used to form multi-layer structures. The teachings of the '630 patent are hereby incorporated herein by reference as if set forth in full herein. Since the filing of the patent application that led to the above noted patent, various papers about conformable contact mask plating (i.e. INSTANT MASKING) and electrochemical fabrication have been published:

1. A. Cohen, G. Zhang, F. Tseng, F. Mansfeld, U. Frodis and P. Will, “EFAB: Batch production of functional, fully-dense metal parts with micro-scale features”, Proc. 9th Solid Freeform Fabrication, The University of Texas at Austin, p 161, August 1998.

2. A. Cohen, G. Zhang, F. Tseng, F. Mansfeld, U. Frodis and P. Will, “EFAB: Rapid, Low-Cost Desktop Micromachining of High Aspect Ratio True 3-D MEMS”, Proc. 12th IEEE Micro Electro Mechanical Systems Workshop, IEEE, p 244, January 1999.

3. A. Cohen, “3-D Micromachining by Electrochemical Fabrication”, Micromachine Devices, March 1999.

4. G. Zhang, A. Cohen, U. Frodis, F. Tseng, F. Mansfeld, and P. Will, “EFAB: Rapid Desktop Manufacturing of True 3-D Microstructures”, Proc. 2nd International Conference on Integrated MicroNanotechnology for Space Applications, The Aerospace Co., April 1999.

5. F. Tseng, U. Frodis, G. Zhang, A. Cohen, F. Mansfeld, and P. Will, “EFAB: High Aspect Ratio, Arbitrary 3-D Metal Microstructures using a Low-Cost Automated Batch Process”, 3rd International Workshop on High Aspect Ratio MicroStructure Technology (HARMST'99), June 1999.

6. A. Cohen, U. Frodis, F. Tseng, G. Zhang, F. Mansfeld, and P. Will, “EFAB: Low-Cost, Automated Electrochemical Batch Fabrication of Arbitrary 3-D Microstructures”, Micromachining and Microfabrication Process Technology, SPIE 1999 Symposium on Micromachining and Microfabrication, September 1999.

7. F. Tseng, G. Zhang, U. Frodis, A. Cohen, F. Mansfeld, and P. Will, “EFAB: High Aspect Ratio, Arbitrary 3-D Metal Microstructures using a Low-Cost Automated Batch Process”, MEMS Symposium, ASME 1999 International Mechanical Engineering Congress and Exposition, November, 1999.

8. A. Cohen, “Electrochemical Fabrication (EFABTM)”, Chapter 19 of The MEMS Handbook, edited by Mohamed Gad-El-Hak, CRC Press, 2002.

9. “Microfabrication—Rapid Prototyping's Killer Application”, pages 1-5 of the Rapid Prototyping Report, CAD/CAM Publishing, Inc., June 1999.

The disclosures of these nine publications are hereby incorporated herein by reference as if set forth in full herein.

The electrochemical deposition process may be carried out in a number of different ways as set forth in the above patent and publications. In one form, this process involves the execution of three separate operations during the formation of each layer of the structure that is to be formed:
(1) Selectively depositing at least one material by electrodeposition upon one or more desired regions of a substrate.
(2) Then, blanket depositing at least one additional material by electrodeposition so that the additional deposit covers both the regions that were previously selectively deposited onto, and the regions of the substrate that did not receive any previously applied selective depositions.
(3) Finally, planarizing the materials deposited during the first and second operations to produce a smoothed surface of a first layer of desired thickness having at least one region containing the at least one material and at least one region containing at least the one additional material.

After formation of the first layer, one or more additional layers may be formed adjacent to the immediately preceding layer and adhered to the smoothed surface of that preceding layer. These additional layers are formed by repeating the first through third operations one or more times wherein the formation of each subsequent layer treats the previously formed layers and the initial substrate as a new and thickening substrate.

Once the formation of all layers has been completed, at least a portion of at least one of the materials deposited is generally removed by an etching process to expose or release the three-dimensional structure that was intended to be formed.

The preferred method of performing the selective electrodeposition involved in the first operation is by conformable contact mask plating. In this type of plating, one or more conformable contact (CC) masks are first formed. The CC masks include a support structure onto which a patterned conformable dielectric material is adhered or formed. The conformable material for each mask is shaped in accordance with a particular cross-section of material to be plated. At least one CC mask is needed for each unique cross-sectional pattern that is to be plated.

The support for a CC mask is typically a plate-like structure formed of a metal that is to be selectively electroplated and from which material to be plated will be dissolved. In this typical approach, the support will act as an anode in an electroplating process. In an alternative approach, the support may instead be a porous or otherwise perforated material through which deposition material will pass during an electroplating operation on its way from a distal anode to a deposition surface. In either approach, it is possible for CC masks to share a common support, i.e. the patterns of conformable dielectric material for plating multiple layers of material may be located in different areas of a single support structure. When a single support structure contains multiple plating patterns, the entire structure is referred to as the CC mask while the individual plating masks may be referred to as “submasks”. In the present application such a distinction will be made only when relevant to a specific point being made.

In preparation for performing the selective deposition of the first operation, the conformable portion of the CC mask is placed in registration with and pressed against a selected portion of the substrate (or onto a previously formed layer or onto a previously deposited portion of a layer) on which deposition is to occur. The pressing together of the CC mask and substrate occur in such a way that all openings, in the conformable portions of the CC mask contain plating solution. The conformable material of the CC mask that contacts the substrate acts as a barrier to electrodeposition while the openings in the CC mask that are filled with electroplating solution act as pathways for transferring material from an anode (e.g. the CC mask support) to the non-contacted portions of the substrate (which act as a cathode during the plating operation) when an appropriate potential and/or current are supplied.

An example of a CC mask and CC mask plating are shown in FIGS. 1A-1C. FIG. 1A shows a side view of a CC mask 8 consisting of a conformable or deformable (e.g. elastomeric) insulator 10 patterned on an anode 12. The anode has two functions. FIG. 1A also depicts a substrate 6 separated from mask 8. One is as a supporting material for the patterned insulator 10 to maintain its integrity and alignment since the pattern may be topologically complex (e.g., involving isolated “islands” of insulator material). The other function is as an anode for the electroplating operation. CC mask plating selectively deposits material 22 onto a substrate 6 by simply pressing the insulator against the substrate then electrodepositing material through apertures 26a and 26b in the insulator as shown in FIG. 1B. After deposition, the CC mask is separated, preferably non-destructively, from the substrate 6 as shown in FIG. 1C. The CC mask plating process is distinct from a “through-mask” plating process in that in a through-mask plating process the separation of the masking material from the substrate would occur destructively. As with through-mask plating, CC mask plating deposits material selectively and simultaneously over the entire layer. The plated region may consist of one or more isolated plating regions where these isolated plating regions may belong to a single structure that is being formed or may belong to multiple structures that are being formed simultaneously. In CC mask plating as individual masks are not intentionally destroyed in the removal process, they may be usable in multiple plating operations.

Another example of a CC mask and CC mask plating is shown in FIGS. 1D-1F. FIG. 1D shows an anode 12′ separated from a mask 8′ that comprises a patterned conformable material 10′ and a support structure 20. FIG. 1D also depicts substrate 6 separated from the mask 8′. FIG. 1E illustrates the mask 8′ being brought into contact with the substrate 6. FIG. 1F illustrates the deposit 22′ that results from conducting a current from the anode 12′ to the substrate 6. FIG. 1G illustrates the deposit 22′ on substrate 6 after separation from mask 8′. In this example, an appropriate electrolyte is located between the substrate 6 and the anode 12′ and a current of ions coming from one or both of the solution and the anode are conducted through the opening in the mask to the substrate where material is deposited. This type of mask may be referred to as an anodeless INSTANT MASK™ (AIM) or as an anodeless conformable contact (ACC) mask.

Unlike through-mask plating, CC mask plating allows CC masks to be formed completely separate from the fabrication of the substrate on which plating is to occur (e.g. separate from a three-dimensional (3D) structure that is being formed). CC masks may be formed in a variety of ways, for example, a photolithographic process may be used. All masks can be generated simultaneously, prior to structure fabrication rather than during it. This separation makes possible a simple, low-cost, automated, self-contained, and internally-clean “desktop factory” that can be installed almost anywhere to fabricate 3D structures, leaving any required clean room processes, such as photolithography to be performed by service bureaus or the like.

An example of the electrochemical fabrication process discussed above is illustrated in FIGS. 2A-2F. These figures show that the process involves deposition of a first material 2 which is a sacrificial material and a second material 4 which is a structural material. The CC mask 8, in this example, includes a patterned conformable material (e.g. an elastomeric dielectric material) 10 and a support 12 which is made from deposition material 2. The conformal portion of the CC mask is pressed against substrate 6 with a plating solution 14 located within the openings 16 in the conformable material 10. An electric current, from power supply 18, is then passed through the plating solution 14 via (a) support 12 which doubles as an anode and (b) substrate 6 which doubles as a cathode. FIG. 2A, illustrates that the passing of current causes material 2 within the plating solution and material 2 from the anode 12 to be selectively transferred to and plated on the cathode 6. After electroplating the first deposition material 2 onto the substrate 6 using CC mask 8, the CC mask 8 is removed as shown in FIG. 2B. FIG. 2C depicts the second deposition material 4 as having been blanket-deposited (i.e. non-selectively deposited) over the previously deposited first deposition material 2 as well as over the other portions of the substrate 6. The blanket deposition occurs by electroplating from an anode (not shown), composed of the second material, through an appropriate plating solution (not shown), and to the cathode/substrate 6. The entire two-material layer is then planarized to achieve precise thickness and flatness as shown in FIG. 2D. After repetition of this process for all layers, the multi-layer structure 20 formed of the second material 4 (i.e. structural material) is embedded in first material 2 (i.e. sacrificial material) as shown in FIG. 2E. The embedded structure is etched to yield the desired device, i.e. structure 20, as shown in FIG. 2F.

Various components of an exemplary manual electrochemical fabrication system 32 are shown in FIGS. 3A-3C. The system 32 consists of several subsystems 34, 36, 38, and 40. The substrate holding subsystem 34 is depicted in the upper portions of each of FIGS. 3A to 3C and includes several components: (1) a carrier 48, (2) a metal substrate 6 onto which the layers are deposited, and (3) a linear slide 42 capable of moving the substrate 6 up and down relative to the carrier 48 in response to drive force from actuator 44. Subsystem 34 also includes an indicator 46 for measuring differences in vertical position of the substrate which may be used in setting or determining layer thicknesses and/or deposition thicknesses. The subsystem 34 further includes feet 68 for carrier 48 which can be precisely mounted on subsystem 36.

The CC mask subsystem 36 shown in the lower portion of FIG. 3A includes several components: (1) a CC mask 8 that is actually made up of a number of CC masks (i.e. submasks) that share a common support/anode 12, (2) precision X-stage 54, (3) precision Y-stage 56, (4) frame 72 on which the feet 68 of subsystem 34 can mount, and (5) a tank 58 for containing the electrolyte 16. Subsystems 34 and 36 also include appropriate electrical connections (not shown) for connecting to an appropriate power source for driving the CC masking process.

The blanket deposition subsystem 38 is shown in the lower portion of FIG. 3B and includes several components: (1) an anode 62, (2) an electrolyte tank 64 for holding plating solution 66, and (3) frame 74 on which the feet 68 of subsystem 34 may sit. Subsystem 38 also includes appropriate electrical connections (not shown) for connecting the anode to an appropriate power supply for driving the blanket deposition process.

The planarization subsystem 40 is shown in the lower portion of FIG. 3C and includes a lapping plate 52 and associated motion and control systems (not shown) for planarizing the depositions.

Another method for forming microstructures from electroplated metals (i.e. using electrochemical fabrication techniques) is taught in U.S. Pat. No. 5,190,637 to Henry Guckel, entitled “Formation of Microstructures by Multiple Level Deep X-ray Lithography with Sacrificial Metal layers. This patent teaches the formation of metal structure utilizing mask exposures. A first layer of a primary metal is electroplated onto an exposed plating base to fill a void in a photoresist, the photoresist is then removed and a secondary metal is electroplated over the first layer and over the plating base. The exposed surface of the secondary metal is then machined down to a height which exposes the first metal to produce a flat uniform surface extending across the both the primary and secondary metals. Formation of a second layer may then begin by applying a photoresist layer over the first layer and then repeating the process used to produce the first layer. The process is then repeated until the entire structure is formed and the secondary metal is removed by etching. The photoresist is formed over the plating base or previous layer by casting and the voids in the photoresist are formed by exposure of the photoresist through a patterned mask via X-rays or UV radiation.

A need remains for enhanced build operation diagnostics. A further need remains for minimizing wasted time, effort, and/or material.

### SUMMARY OF THE INVENTION

It is an object of various aspects of the invention to provide a microscale or mesoscale fabrication process that provides enhanced build problem diagnostics.

It is an object of various aspects of the invention to provide a microscale or mesoscale fabrication process that provides for enhanced determination of the successful or unsuccessful completion of attempted build processes.

It is an object of various aspects of the invention to provide a microscale or mesoscale fabrication process that includes more timely recognition when a faulty build process has occurred or is believed likely to have occurred.

It is an object of various aspects of the invention to provide a microscale or mesoscale fabrication process that reduces wasted fabrication time when a faulty build process has occurred or is believed likely to have occurred.

It is an object of various aspects of the invention to provide a microscale or mesoscale fabrication process that reduces wasted fabrication effort when a faulty build process has occurred or is believed likely to have occurred.

Other objects and advantages of various aspects of the invention will be apparent to those of skill in the art upon review of the teachings herein. The various aspects of the invention, set forth explicitly herein or otherwise ascertained from the teachings herein, may address one or more of the above objects alone or in combination, or alternatively may address some other object of the invention ascertained from the teachings herein. It is not necessarily intended that all objects be addressed by any single aspect of the invention even though that may be the case with regard to some aspects.

A first aspect of the invention provides an electrochemical fabrication process for producing a three-dimensional structure from a plurality of adhered layers, the process including: (A) selectively depositing at least a portion of a layer onto the substrate, wherein the substrate may include previously deposited material; (B) forming a plurality of layers such that successive layers are formed adjacent to and adhered to previously deposited layers, wherein said forming includes repeating operation (A) a plurality of times; wherein at least a plurality of the selective depositing operations include: (1) adhering a mask to or locating a preformed mask in contact with or in proximity to a substrate; (2) in presence of a plating solution, conducting an electric current between an anode and the substrate through the at least one opening in the mask, such that a selected deposition material is deposited onto the substrate to form at least a portion of a layer; and (3) removing the mask from the substrate; wherein during one or more layer formation processes or after one or more layer formation processes at least one inspection occurs that is capable of identifying a plurality of process failures and wherein at least one of any failures is correlated to a potential corrective action and at least one corrective action is taken to allow successful fabrication of the structure to continue.

A second aspect of the invention provides an electrochemical fabrication process for producing a three-dimensional structure from a plurality of adhered layers, the process including: (A) selectively depositing at least a portion of a layer onto the substrate, wherein the substrate may include previously deposited material; (B) forming a plurality of layers such that successive layers are formed adjacent to and adhered to previously deposited layers, wherein said forming includes repeating operation (A) a plurality of times; wherein at least a plurality of the selective depositing operations include: (1) adhering a mask to or locating a preformed mask in contact with or in proximity to a substrate; (2) in presence of a plating solution, conducting an electric current between an anode and the substrate through the at least one opening in the mask, such that a selected deposition material is deposited onto the substrate to form at least a portion of a layer; and (3) removing the mask from the substrate; wherein during, or after, formation of a given layer, the layer is inspected or formation parameters are compared to anticipated parameter values such that a determination concerning the existence of a plurality of potential build problems is made wherein if it is determined that the layer was not formed correctly, at least a portion of material deposited in association with the layer is removed and replacement material is deposited.

A third aspect of the invention provides a process for forming a multilayer three-dimensional structure, including: (A) forming and adhering a layer of material to a substrate, wherein the substrate may include previously formed layers; (B) repeating the forming and adhering operation of (a) a plurality of times to build up a three-dimensional structure from a plurality of adhered layers; wherein the formation of each of at least a plurality of layers, includes: (1) obtaining a selective pattern of deposition of a first material having voids, including at least one of: (a) selectively depositing a first material onto the substrate such that at least one void remains, wherein the depositing includes: (i) adhering a mask and a surface of the substrate together or bringing a preformed mask into contact with or in proximity to the substrate in preparation for depositing a first material; (ii) depositing the first material onto the substrate with the mask in place; (iii) separating the mask and the substrate to expose the at least one void; or (b) depositing a first material onto the substrate and selectively etching the deposit of the first material to form voids therein, wherein the etching includes: (i) adhering a mask and a surface of the deposited first material together or bring a preformed mask into contact with or in proximity to the substrate; (ii) etching, with the mask in place, into the first material to form at least one void; (iii) separating the mask and the substrate; and (2) depositing a second material into the at least one void, and wherein during, or after, formation of a given layer, the layer is inspected, or formation parameters are compared to anticipated parameter values, such that if it is determined that the layer was not formed correctly, at least a portion of material deposited in association with the layer is removed and replacement material is deposited.

A fourth aspect of the invention provides an electrochemical fabrication process for producing a three-dimensional structure from a plurality of adhered layers, the process including: (A) selectively depositing at least a portion of a layer onto the substrate, wherein the substrate may include previously deposited material; (B) forming a plurality of layers such that successive layers are formed adjacent to and adhered to previously deposited layers, wherein said forming includes repeating operation (A) a plurality of times; wherein at least a plurality of the selective depositing operations include: (1) adhering a mask to or locating a preformed mask in contact with or in proximity to a substrate; (2) depositing onto the substrate a desired material to form at least a portion of a layer; and (3) removing the mask from the substrate; wherein during one or more layer formation processes or after one or more layer formation processes at least one inspection occurs that is capable of identifying a plurality of process failures and wherein at least one of any failures is correlated to a potential corrective action and at least one corrective action is taken to allow successful fabrication of the structure to continue.

A fifth aspect of the invention provides an electrochemical fabrication process for producing a three-dimensional structure from a plurality of adhered layers, the process including: (A) selectively depositing at least a portion of a layer onto the substrate, wherein the substrate may include previously deposited material; (B) forming a plurality of layers such that successive layers are formed adjacent to and adhered to previously deposited layers, wherein said forming includes repeating operation (A) a plurality of times; wherein at least a plurality of the selective depositing operations include: (1) adhering a mask to or locating a preformed mask in contact with or in proximity to a substrate; (2) depositing onto the substrate a desired material to form at least a portion of a layer; and (3) removing the mask from the substrate; wherein during, or after, formation of a given layer, the layer is inspected or formation parameters are compared to anticipated parameter values such that a determination concerning the existence of a plurality of potential build problems is made wherein if it is determined that the layer was not formed correctly, at least a portion of material deposited in association with the layer is removed and replacement material is deposited.

Further aspects of the invention will be understood by those of skill in the art upon reviewing the teachings herein. Other aspects of the invention may involve combinations of the above noted aspects of the invention. Other aspects of the invention may involve apparatus that can be used in implementing one or more of the above method aspects of the invention. These other aspects of the invention may provide various combinations of the aspects presented above as well as provide other configurations, structures, functional relationships, and processes that have not been specifically set forth above.

### BRIEF DESCRIPTION OF THE DRAWINGS

FIGS. 1A-1C schematically depict side views of various stages of a CC mask plating process, while FIGS. 1D-G schematically depict a side views of various stages of a CC mask plating process using a different type of CC mask.

FIGS. 2A-2F schematically depict side views of various stages of an electrochemical fabrication process as applied to the formation of a particular structure where a sacrificial material is selectively deposited while a structural material is blanket deposited.

FIGS. 3A-3C schematically depict side views of various example subassemblies that may be used in manually implementing the electrochemical fabrication method depicted in FIGS. 2A-2F.

FIGS. 4A-4I schematically depict the formation of a first layer of a structure using adhered mask plating where the blanket deposition of a second material overlays both the openings between deposition locations of a first material and the first material itself

FIG. 5 illustrates a block diagram of rework elements of a first generalized embodiment.

FIG. 6 provides a block diagram of rework elements of a second generalized embodiment.

FIGS. 7A-7B provides a flowchart of a third generalized embodiment where build operations are specified along with failure or problem recognition and corrective action decisions and corrective action implementation.

FIG. 8A-8B provides a flowchart of a fourth generalized embodiment where it is assumed all layers have been formed and that post processing operations are to be performed and that failure or problem recognition is made during post processing operations and that appropriate corrective actions are taken.

FIG. 9A provides a block diagram listing examples of build problems that may be recognized, monitored or detected as part of an embodiment of the present invention.

FIG. 9B provides examples of various rework or corrective action operations that may be used in getting the building operations back on track when build problems are discovered.

### DETAILED DESCRIPTION

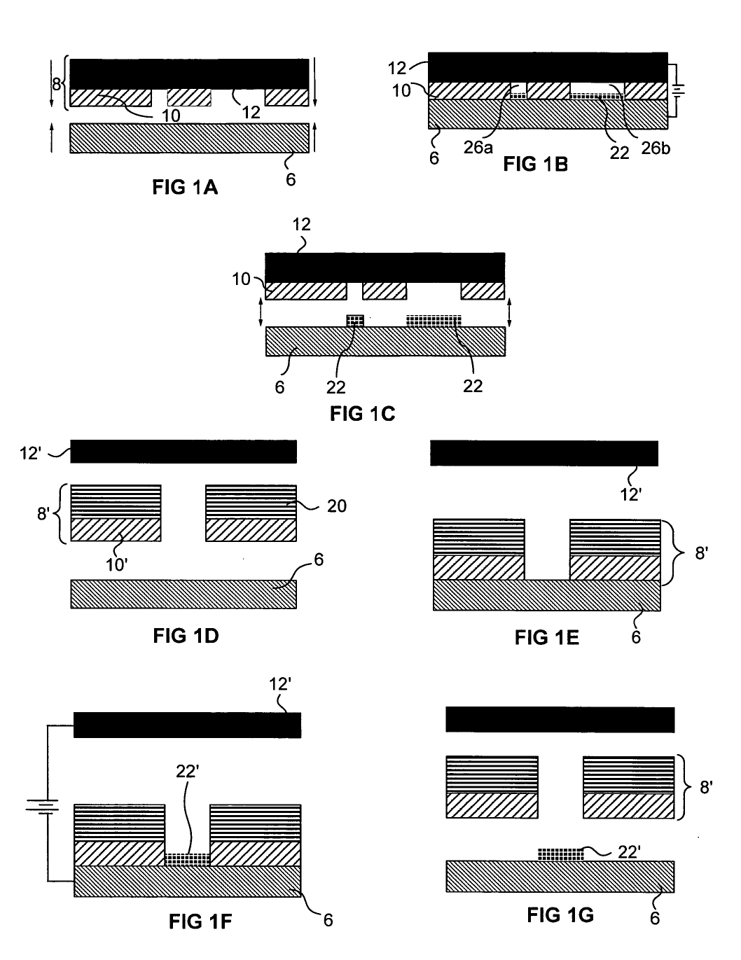

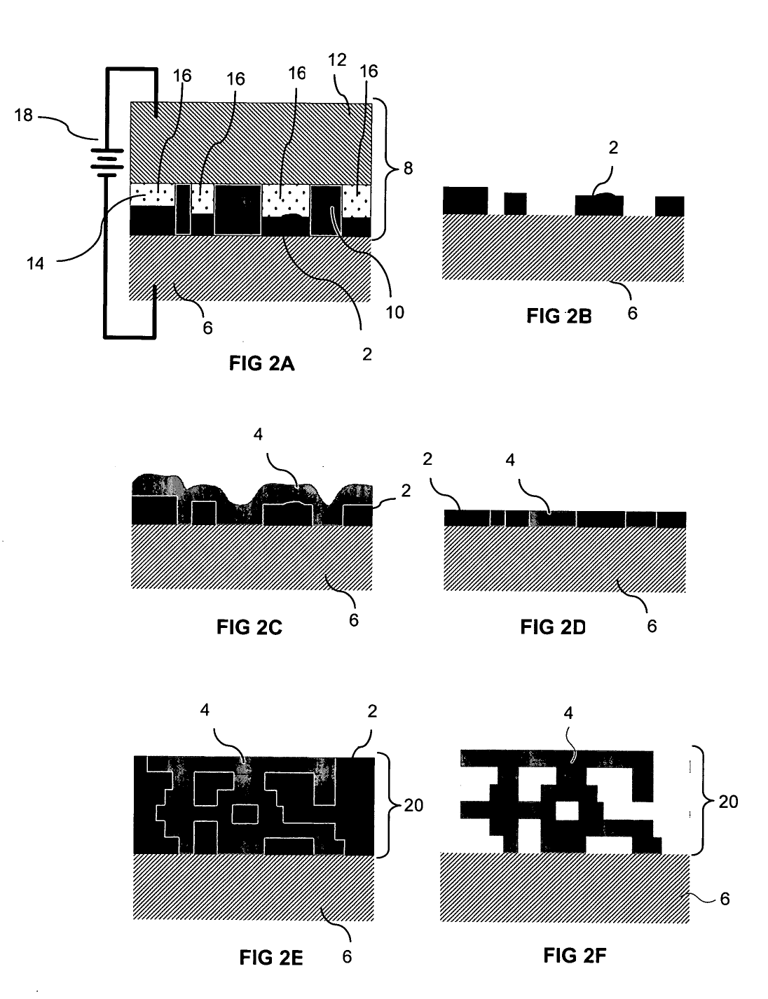

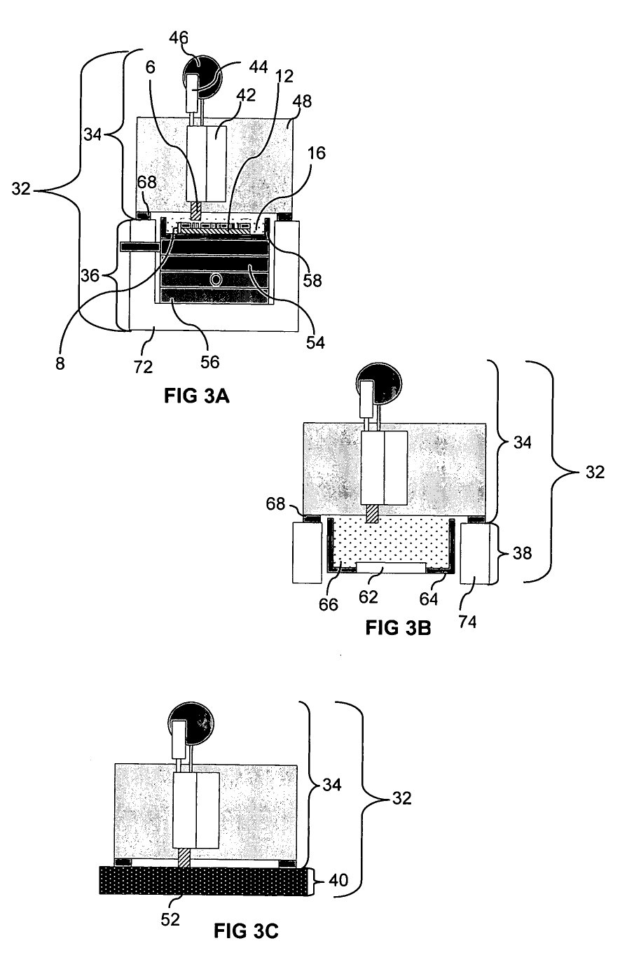

FIGS. 1A-1G, 2A-2F, and 3A-3C illustrate various features of one form of electrochemical fabrication that are known. Other electrochemical fabrication techniques are set forth in the '630 patent referenced above, in the various previously incorporated publications, in various other patents and patent applications incorporated herein by reference, still others may be derived from combinations of various approaches described in these publications, patents, and applications, or are otherwise known or ascertainable by those of skill in the art from the teachings set forth herein. All of these techniques may be combined with those of the various embodiments of various aspects of the invention to yield enhanced embodiments. Still other embodiments may be derived from combinations of the various embodiments explicitly set forth herein.

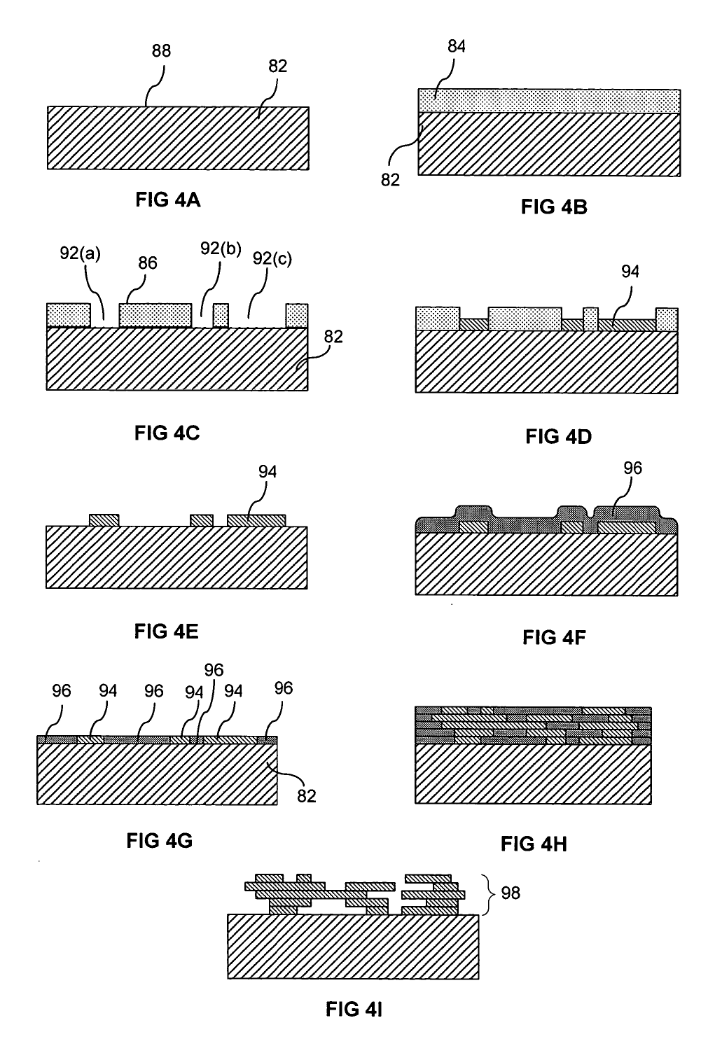

FIGS. 4A-4I illustrate various stages in the formation of a single layer of a multi-layer fabrication process where a second metal is deposited on a first metal as well as in openings in the first metal where its deposition forms part of the layer. In FIG. 4A, a side view of a substrate 82 is shown, onto which patternable photoresist 84 is cast as shown in FIG. 4B. In FIG. 4C, a pattern of resist is shown that results from the curing, exposing, and developing of the resist. The patterning of the photoresist 84 results in openings or apertures 92(a)-92(c) extending from a surface 86 of the photoresist through the thickness of the photoresist to surface 88 of the substrate 82. In FIG. 4D, a metal 94 (e.g. nickel) is shown as having been electroplated into the openings 92(a)-92(c). In FIG. 4E, the photoresist has been removed (i.e. chemically stripped) from the substrate to expose regions of the substrate 82 which are not covered with the first metal 94. In FIG. 4F, a second metal 96 (e.g., silver) is shown as having been blanket electroplated over the entire exposed portions of the substrate 82 (which is conductive) and over the first metal 94 (which is also conductive). FIG. 4G depicts the completed first layer of the structure which has resulted from the planarization of the first and second metals down to a height that exposes the first metal and sets a thickness for the first layer. In FIG. 4H the result of repeating the process steps shown in FIGS. 4B-4G several times to form a multi-layer structure are shown where each layer consists of two materials. For most applications, one of these materials is removed as shown in FIG. 4I to yield a desired 3-D structure 98 (e.g. component or device).

The various embodiments, alternatives, and techniques disclosed herein may form multi-layer structures using a single patterning technique on all layers or using different patterning techniques on different layers. For example, different types of patterning masks and masking techniques may be used or even techniques that perform direct selective depositions without the need for masking. Proximity masks and masking operations (i.e. operations that use masks that at least partially selectively shield a substrate by their proximity to the substrate even if contact is not made) may be used, and adhered masks and masking operations (masks and operations that use masks that are adhered to a substrate onto which selective deposition or etching is to occur as opposed to only being contacted to it) may be used. Patterning operations may be used in selectively depositing material and/or may be used in the selective etching of material. Selectively etched regions may be selectively filled in or filled in via blanket deposition, or the like, with a different desired material. In some embodiments, the layer-by-layer build up may involve the simultaneous formation of portions of multiple layers. In some embodiments, depositions made in association with some layer levels may result in depositions to regions associated with other layer levels. Such use of selective etching and interlaced material deposited in association with multiple layers are described in U.S. patent application Ser. No. 10/434,519, by Smalley, and entitled “Methods of and Apparatus for Electrochemically Fabricating Structures Via Interlaced Layers or Via Selective Etching and Filling of Voids layer elements” which is hereby incorporated herein by reference as if set forth in full.

For example, the enhanced contact mask mating techniques may be used in combination with conformable contact masks and/or non-conformable contact masks and masking operations on some layers while other layers may be formed using contact masks. As another example, formation of some layers may involve the selective deposition of one or more materials, while the formation of other layers may involve selective etching of materials, while the formation of still other layers involves the both selective deposition and selective etching.

U.S. patent application Ser. Nos. 60/379,132 and 10/434,494 both by Zhang and Cohen, and both entitled “Methods and Apparatus for Monitoring Deposition Quality During Conformable Contact Mask Plating Operations” are hereby incorporated herein by reference as if set forth in full.

The '494 application teaches that measurements of cell voltage during plating can provide information on several different plating conditions/results and that for each deposition by conformable contact masking, the deposition process can be monitored wherein problems may be recognized during deposition or after the completion of a deposition. It also teaches that based on an analysis of the resulting voltage curves in comparison to an anticipated curve or in comparison to a predefined acceptability or rejection criteria, a decision can be made as to whether or not the formation process can continue on course, whether the process should be aborted, or whether some form of remedial or corrective action should be taken.

The '494 application further teaches that for each deposition by conformable contact masking, the deposition process can be monitored wherein problems may be recognized during deposition or after the completion of a deposition. Based on an analysis of the resulting voltage curves in comparison to an anticipated curve or in comparison to a predefined acceptability or rejection criteria, a decision can be made as to whether or not the formation process can continue on course, whether the process should be aborted, or whether some form of remedial or corrective action should be taken. Problem detection may occur by operator review and analysis of one or more monitored electric signals (e.g. voltages), by automated system recognition, or by a combination of the two. Depending on the level of automation of the system and the believed severity of the problem, remedial action may be performed manually by an operator or under automated system control and it may involve a number of different operations:
(1) Visual or secondary inspections may be performed to confirm that a problem occurred or to determine the severity of the problem so as to aid in making decisions on the most appropriate forms of additional remedial action to take, if any;
(2) If the offending deposition is still underway at the time of problem recognition,
   i. it may be aborted; or
   ii. it may be allowed to continue for a time;
(3) One or more additional depositions may be allowed to occur (e.g. to ensure full lateral support of the deposited structure)
(4) A trimming process (e.g. planarization process by mechanical lapping or by CMP) may be implemented to remove all of, or just a portion of, the offending deposit.
(5) Complete or partial redeposition of the offending pattern may be undertaken
   i. the same mask may be used in one or more subsequent attempts; or
   ii an alternate mask may be used on one or more subsequent attempts; and
(6) If an optimal redeposition cannot be obtained, within a certain number of attempts, an automated system may be programmed to interrupt the formation process, pending operator intervention or to continue with the formation process while leaving behind an appropriate log of the issues encountered and remedial steps attempted.

The '494 application even further teaches that various embodiments may be implemented using a single rejection criteria (e.g. shorting recognition) or using multiple rejection criteria. Each rejection criteria used may result in execution of the same remedial process or different rejection criteria may result in implementation of different remedial actions. In some embodiments remedial action may involve each of operations (1) to (6) as noted above. In other embodiments only a subset of operations (1) to (6) may be used, for example (2)(ii) followed by (4) followed by (5)(b), and then by (6), if necessary. Each time operation (6) is encountered when a certain number of attempts have not yet been made, the remedial actions may be different. In some embodiments, if a problem associated with a given layer is believed to be the result of a problem on a previous layer or if the remedial steps taken on the present layer may have negatively affected one or more previous layers, not only may one or more depositions associated with the present layer be trimmed away, but material may be trimmed from one or more previous layers. Redepositions of material for the present layer and for any previous layers of removed material may also be performed. In some embodiments trimming operations may involve anodic etching as opposed to or in addition to other trimming processes.

Various embodiments of the invention of the present application extend the embodiments disclosed in the '494 application, provide for detection of other build process failings, and/or provide for the taking of different or additional remedial actions. Various other problem recognition possibilities and remedial operation possibilities, and combinations will be apparent to those of skill in the art after review of the teachings herein.

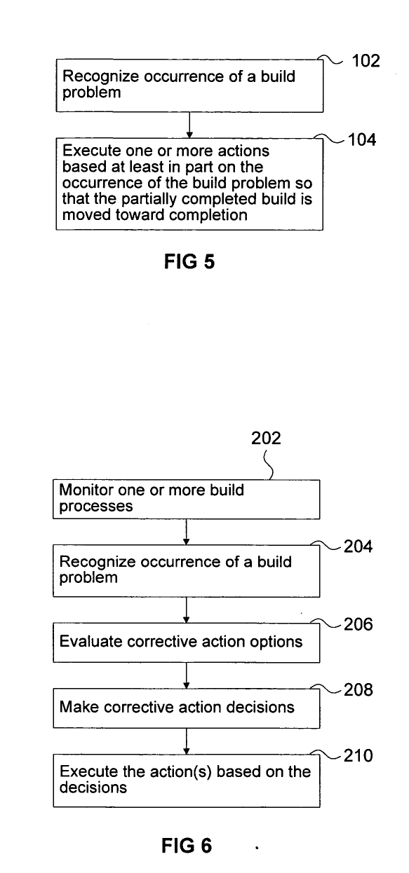

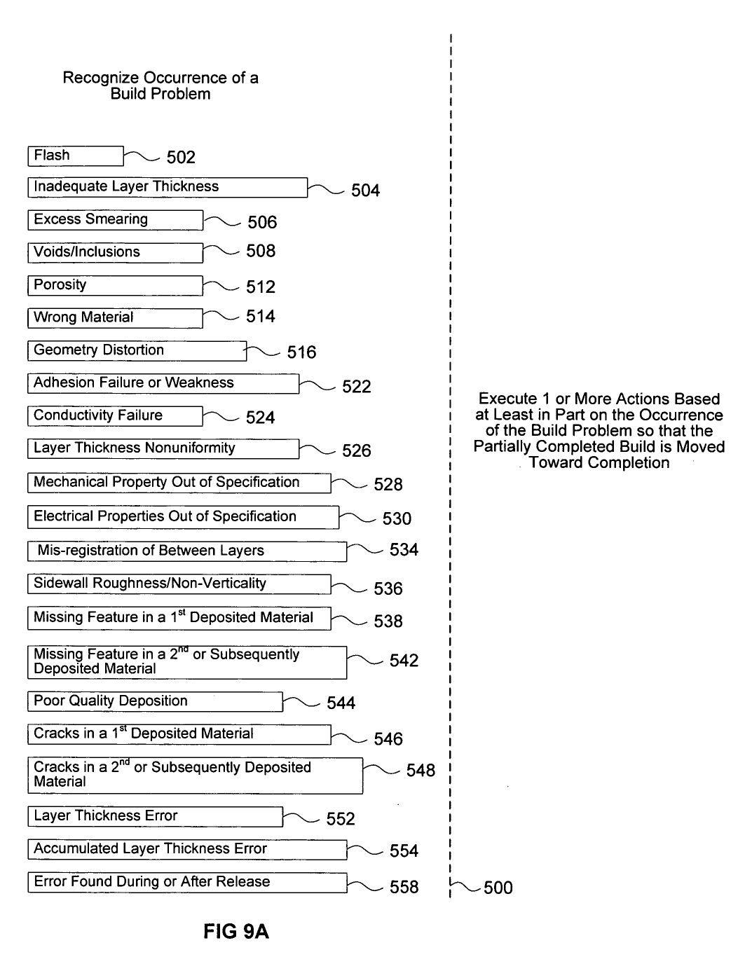

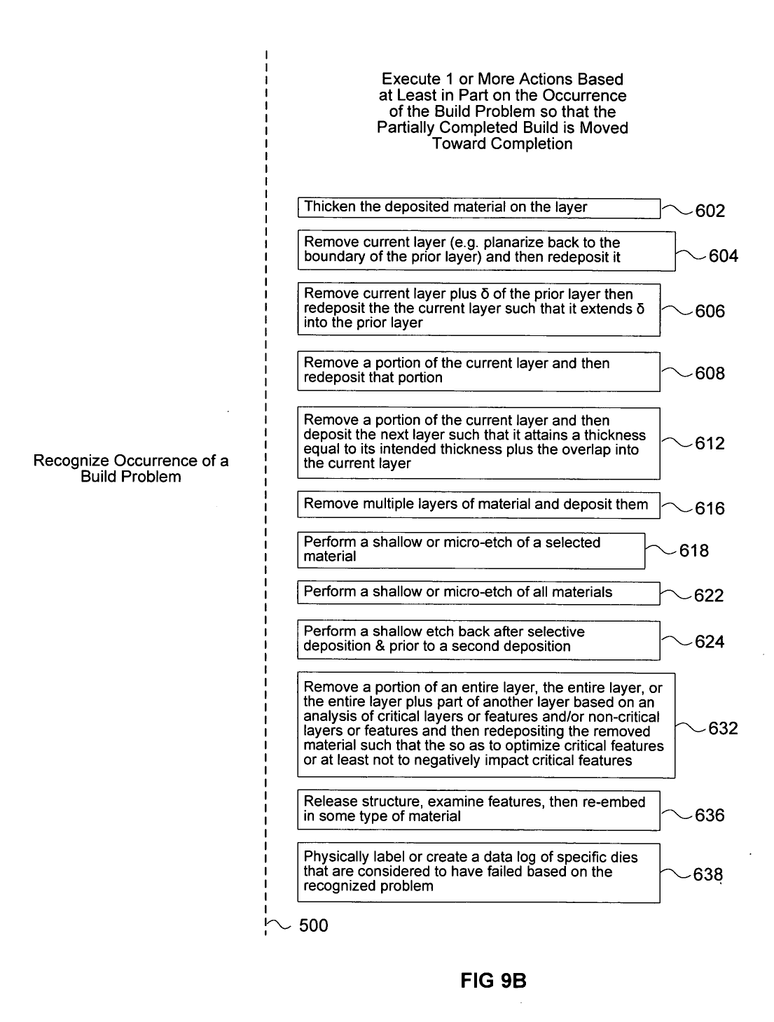

FIG. 5 illustrates a block diagram of rework elements of a first generalized embodiment. The rework elements may be considered to start with the recognition of a build problem as indicated by block 102. After recognition of the problem, the process moves forward to block 104 which calls for the taking of one or more actions based, at least in part, on the occurrence of the problem. The remedial actions are taken to allow the building of the structure to continue toward completion without needing to restart the formation of the structure from the beginning. A recognized problem may be one or more of those set forth in elements 502-558 of FIG. 9 or it may be some other problem and the remedial action may be one or more of the actions set forth in elements 602-638 of FIG. 9 or it may be some other action.

FIG. 6 provides a block diagram of rework elements of a second generalized embodiment. The rework elements start with monitoring selected build operations as indicated by block 202. The monitoring may occur during performance of a selected build operation or after performance of the operation. The monitoring may be appropriate for determining one or more of the build problems set forth in elements 502-558 of FIG. 9 or may be appropriate for ascertaining some other problem. Next, a problem or failure in the build process or in the result of the build process is recognized as indicated block 204. In some alternatives, it may not be necessary to recognize the existence of a particular or specific problem but simply to conclude that a certain amount or type of rework is necessary or is to be performed. The recognition of the problem may occur in a variety of ways. In some implementations it may be recognized through operator inspection of the structure or data recorded during the process while in other implementations recognition may occur via an automated process. Next, possibly based on specific details of the failure, potential corrective action options are determined and their applicability is evaluated as indicated by block 206 and thereafter decisions on the corrective action or actions to take are made as indicated by block 208. Finally the corrective actions are taken as indicated in block 210.

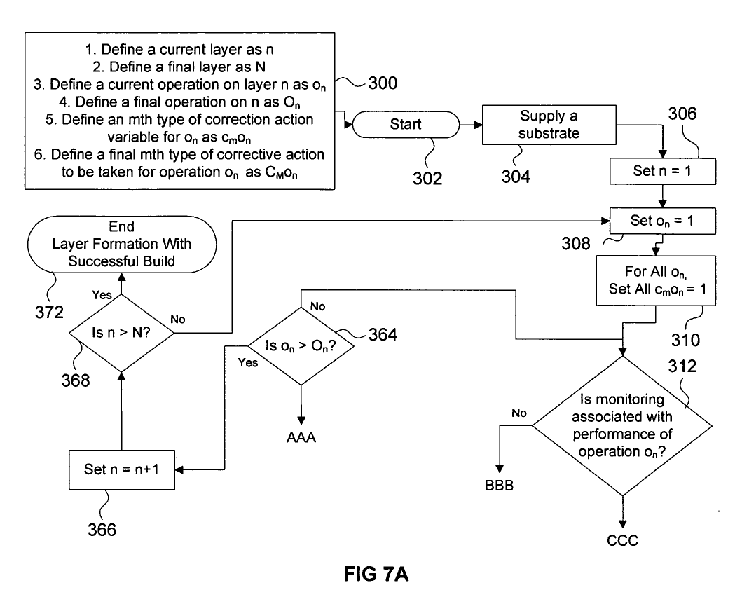

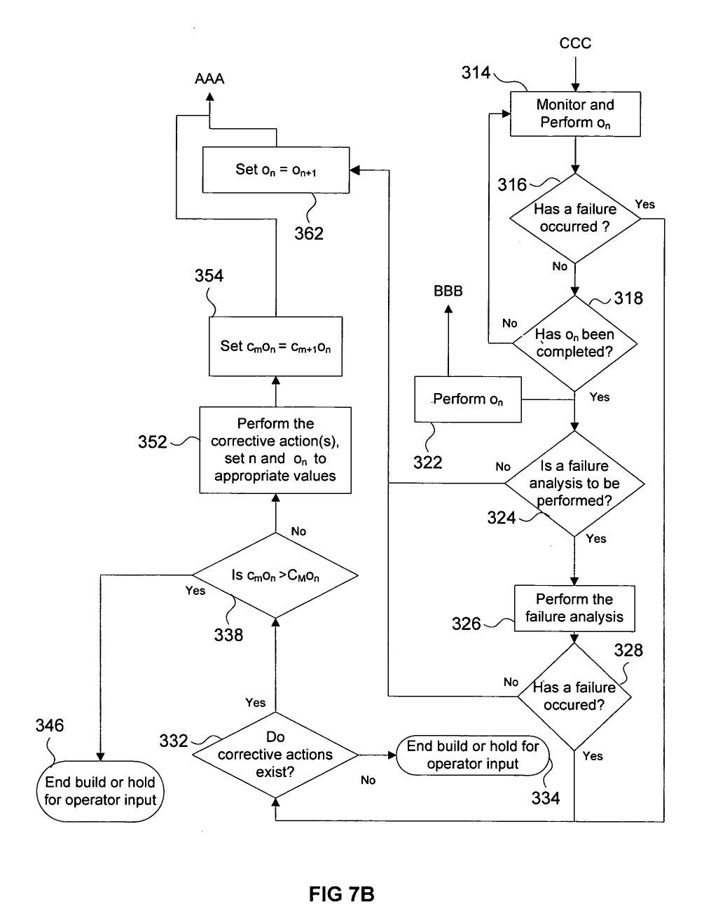

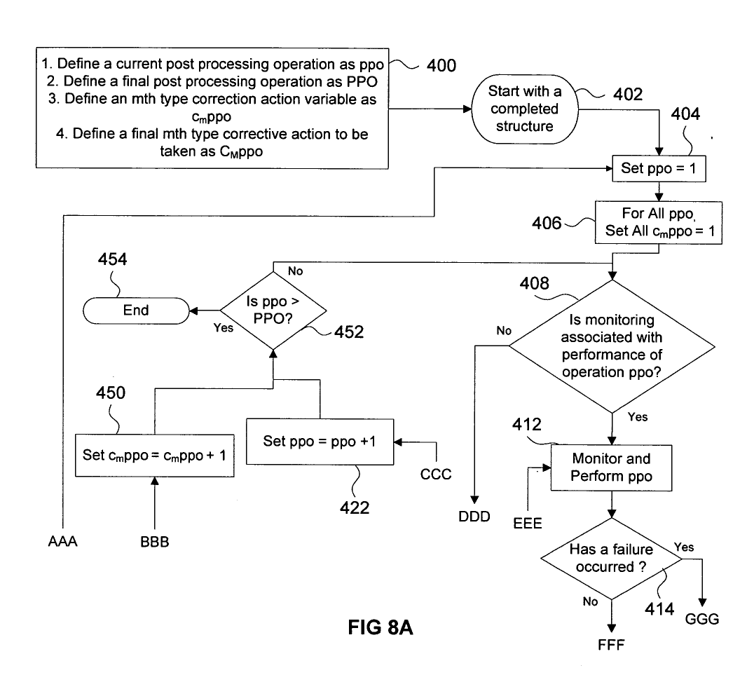

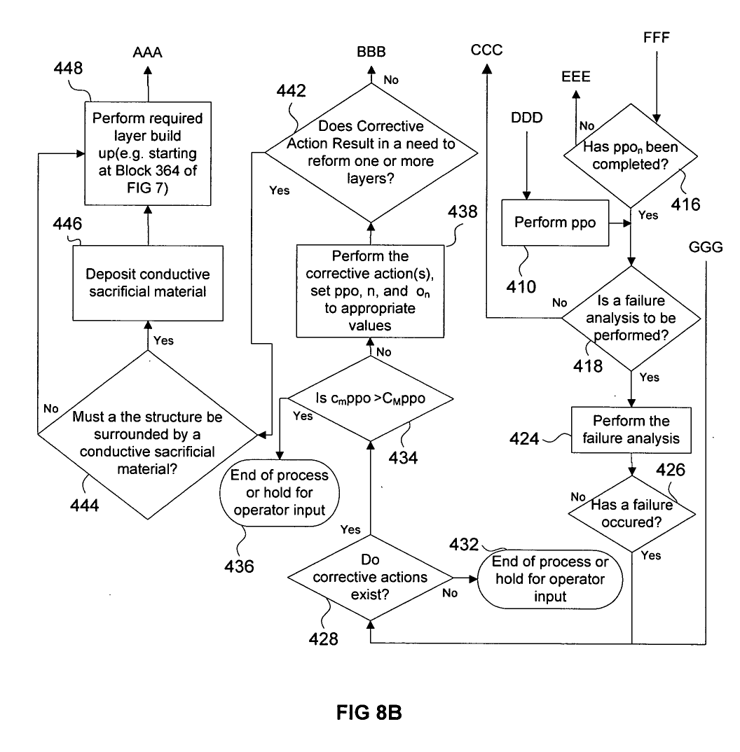

FIGS. 7A-7B provide a flowchart of a third generalized embodiment where build operations are specified along with failure or problem recognition and corrective action decisions and corrective action implementation. Elements AAA, BBB, and CCC are simply used to connect the process flow between the first half of the flow chart shown in FIG. 7A and the second half of the flow chart shown in FIG. 7B.

The process of FIGS. 7A and 7B begins with element 302 based on the definitions provided in block 300. From element 302 the process proceeds to block 304, which calls for the supplying of a substrate on which a structure will be formed. The substrate may take any of a variety of forms. For example, it may be a conductive material, a dielectric material such as a polymer or a ceramic, it may be a substrate that includes a preexisting structure such as an integrated circuit a microdevice formed via an EFAB building process or via a silicon based MEMS process.

The process then proceeds to elements 306, 308 and 310 which respectively call for setting variable n to 1, variable oₙ to 1 and setting all variables cₘoₙ to 1.

The process then moves forward to decision block 312 which inquires as to whether or not the performance of operation oₙ will be monitored. If the answer is no the process moves forward to element 322 which calls for the performance oₙ after which the process moves forward to element 324 which will be discussed hereinafter.

If the answer to the inquiry of block 312 is “yes” the process moves forward to element 314 which calls for the monitoring and performance of operation oₙ. During the monitoring and performance of operation 314 the process moves forward to element 316 which inquires as to whether or not a failure has occurred. If it has, the process moves forward to element 332 which will be discussed hereinafter. If no failure has occurred the process moves forward to decision block 318 which inquires as to whether operation oₙ has been completed. If the answer to this inquiry is “no” the process loops back to element 314. If the answer to this inquiry is “yes” the process moves forward to decision block 324 which inquires as to whether or not a failure analysis is to be performed. If the answer to this inquiry is no the process moves forward to element 362 which will be discussed hereinafter. If the answer to this inquiry is “yes” the process moves to element 326 which calls for the performance of the failure analysis. Next the process moves forward to decision block 328 which inquires as to whether or not a failure has occurred. If the answer to this question is “no” the process moves forward to element 362 but if the answer is “yes” the process moves forward to decision block 332.

Decision block 332 inquires as to whether any corrective actions exist for correcting the failure. If the answer is “no” the process proceeds to element 334 which calls for the end of the build process or at least a holding of the process to wait for operator input. If the answer to the inquiry of decision block 332 is “yes” the process moves forward to decision block 338 which inquires as to whether or not the n^{th} type correction action for operation oₙ is greater than a final n^{th} type corrective action associated with oₙ. If the answer to this inquiry is “yes” the process moves forward to element 346 and the process either ends or is put on hold for further operator input. If the answer to the inquiry of decision block 338 is “no” the process moves forward to block 352 which calls for the performance of a corrective action or actions as well as the setting of layer variable n and operation oₙ to appropriate values. The value of n and the value of oₙ may change as a result of the corrective actions for various reasons, for example, as a result of the removal of deposits associated with previous operations on layer n or even the removal of deposits associated with previous layers.

From block 352 the process moves forward to block 354 which calls for setting variable cₘoₙ to a value cₘ₊₁oₙ. From block 354 the process moves forward to block 364.

As indicated previously, “no” responses to the decision blocks of elements 324 and 328 cause the process to move forward to block 362. Block 362 calls for incrementing variable oₙ to a value of oₙ₊₁.

From element 362 the process moves forward to decision block 364 which inquires as to whether or not oₙ is greater than Oₙ. If the answer to this inquiry is “no” the process loops back to block 312 whereas if the answer to this inquiry is “yes” the process moves forward to block 366. Block 366 calls for incrementing the variable n to a value of n+1. Then the process moves forward to decision block 368 which inquires as to whether variable n is greater than N (i.e. the last layer of the structure being built). If the answer to the inquiry of decision block 368 is “no” the process loops back to block 308 whereas if the answer to the inquiry is “yes” the process moves forward to terminator 372 which calls for the end of the layer formation process as the result of a successful building operation.

In some embodiments the process of forming a structure component or device may not actually be completed with the reaching of terminator 372 as various post processing (i.e. post layer formation processing) operations may need to occur, for example, releasing the formed structure from any sacrificial material or potentially from the substrate itself, heat treating the structure to improve interlay adhesion, dicing individual structures from one another, and the like.

Various alternatives to the embodiment of FIGS. 7A and 7B are possible. In some embodiments, the process flow may be simplified based on predetermined decisions as to what process alternatives are available. In some alternatives, failures may occur only in association with selected die that are being simultaneously formed and thus the build process may continue when a failure occurs by simply creating a data log of which dies have failed and/or which dies remain good. The number of failed die may be tracked and if the failure level is excessive, one or more layers of material may be removed (i.e. the process may be pushed back to a point where the failure level is acceptable, possibly even with some room to spare for subsequent failures) and the layer formation process reinitiated from the lower layer number in hopes of achieving a successful build with adequate yield.

FIGS. 8A and 8B provide a flowchart of a fourth generalized embodiment where it is assumed all layers have been formed and that post processing operations are to be performed and that failure or problem recognition is made during post processing operations and that appropriate corrective actions are taken. Elements AAA-GGG as shown in both FIGS. 8A and 8B are simply used to connect the process flow between the first half of the flow chart shown in FIG. 8A and the second half of the flow chart shown in FIG. 8B.

The process of FIGS. 8A and 8B begins with element 402 which calls for the starting of the process based on a completed structure that is going to undergo post processing (i.e. a structure which has all layers already formed). Block 402 takes as an input various definitions as set forth in block 400.

From Block 402 the process moves forward to block 404 which calls for setting a variable ppo equal to 1 and then proceeds to block 406 which calls for setting all values of the variable cmₚₚₒ equal to 1. From block 406 the process proceeds to decision block 408 which inquires as to whether operation ppo will be monitored during its performance. If the answer is “no” the process moves forward to element 410 which calls for the performance of the post processing operation ppo. If the answer to the inquiry of block 408 is “yes” the process moves forward to element 412 which calls for monitoring and performance of process ppo. During the performance of process ppo block 414 is encountered which inquires as to whether the monitoring has resulted in the detection of a failure. If the answer to this inquiry is “yes” the process moves forward to decision block 428 which will be described hereinafter. If the answer to the inquiry of block 414 is “no” the process moves forward to decision block 416 which inquires to whether or not operation ppoₙ has been completed.

If the inquiry of element 416 produces a “no” response the process loops back to element 412. If the inquiry produces a “yes” response the process moves forward to decision block 418. Decision block 418 inquires as to whether a failure analysis is to be performed. If the answer is “no” the process moves forward to block 422 which will be described hereinafter.

If block 418 produces a “yes” response the process moves forward to block 424 which calls for the performance of the failure analysis after which the process moves forward to decision block 426 which inquires as to whether a failure has occurred. If a failure has not occurred the process moves forward to block 422 which calls for incrementing the value of variable ppo to ppo+1 after which the process moves forward to element 452 which will be described hereinafter. If block 426 produces a “yes” response the process moves forward to block 428 which inquires as to whether or not corrective actions exist for the problem or failure encountered. If block 428 produces a negative response the process moves forward to terminator 432 which calls for the end of the process or at least holding for operator input. If the inquiry of block 428 produces a positive response the process moves forward to decision block 434 which inquires as to whether a m^{th} corrective action for post processing operation ppo is greater than a final M^{th} corrective action that may be taken based on a failure associated with process PPO.

If the inquiry produces a positive response the process moves forward to terminator 436 which calls for the end of the process or at least a holding of the process until operator input can be obtained. If the inquiry of block 434 produces a negative response the process moves forward to block 438 which calls for the performance of corrective actions and possibly the setting of a variable n and a variable oₙ to appropriate values. The variable n may be a layer number variable and oₙ may be operation number associated with that layer number. These values may need to be set based on a need to go back and perform one or more operations associated with layer formation. Such a need for going back to perform additional layer formation operations may result from a corrective action that removes one or more layers from what was a completed structure. Block 438 also calls for setting ppo to an appropriate value. This appropriate value may, for example, be an incrementing of ppo by one or retaining ppo at its current value.

From block 438 the process moves forward to decision block 442 which inquires as to whether or not the corrective action resulted in a need to reform one or more layers. If the inquiry produces a “no” response the process moves forward to element 450 which calls for incrementing the m^{th} type correction action variable for operation ppo by 1. From block 450 the process moves forward to decision block 452 which inquires as to whether or not the current post processing operation variable ppo has a value that is greater than a final post processing operation value PPO. If inquiry 452 produces a negative response the process loops back to block 408. If however, block 452 produces a positive response the process moves to terminator 454 and the process ends. Turning back to decision block 442 if a positive response is produced the process moves forward to decision block 444 which inquires as to whether or not the structure needs to be surrounded by a conductive sacrificial material. This requirement may result from an earlier post processing operation where the sacrificial material was removed but since further layer operations are necessary it may be required to reinsert the sacrificial material. If this inquiry produces a negative response the process moves up to block 448 which will be described hereinafter. And if the inquiry produces a positive response the process moves forward to block 446.

Block 446 calls for the deposition of a conductive sacrificial material. After which the process moves forward to block 448 which calls for the performance of the required layer build up operations which, for example, may be incremented by temporarily diverting the present process to block 364 of FIG. 7, completing that process of FIG. 7 and than coming back to block 448. After the operation or operations of block 448 are performed the process loops back to block 404 where post processing operations may be initiated from their original starting point.

In some embodiments, however, not all post processing operations may need to be performed again and in those embodiments the post processing operations may loop back to block 406 or even block 408. Various other alternatives will be apparent to those of skill in the art upon review of the teachings herein.

FIG. 9A provides a block diagram listing examples of build problems that may be recognized, monitored or detected as part of an embodiment of the present invention while FIG. 9B provides examples of various rework or corrective action operations that may be used in getting the building operations back on track when build problems are discovered.

A flash deposit, block 502 of FIG. 9A, if it occurs, typically occurs during selective deposition where the seating of the mask to the substrate is imperfect and material not only becomes deposited in the open regions or voids of the mask but also between the shielding portion of the mask and the substrate. Flash can be hard to detect after an additional material is overlaid on the selectively deposited material. Prior to depositing an additional material visual inspection (e.g. based on color differences under selected light) may be used to determine the presence of flash and a non-aggressive etch may be used to clean up relatively thin flash or flash-like deposits. It is possible that spectroscopic analysis based on light reflected from regions that are to be open may be used to detect regions of flash. Such a visual or spectroscopic analysis may be based on known regions of each type of material from a previous layer along with regions on the present layer where the material is to exist. A complement of a Boolean union of the regions associated with the selectively deposited material would produce the regions where the selectively deposited material should not exist and thus it may be used in determining if the material has inappropriately turned up. Such information may then be used in triggering a blanket or patterned etching with the intent to remove some or all of the flash deposit without excessive impact on the regions where no flash deposit occurred. The etching operation may, for example, be of the chemical or electrochemical type and it may be selective or non-selective to the material of the flash deposit. In other embodiments, it may be possible to detect flash based on a precise thicknesses measurement. In still other embodiments, it may be possible to infer the existence of flash based on monitoring electrical characteristics as noted in U.S. patent application Ser. No. 10/434,494 referenced previously.

In some embodiments, the rework operation selected for overcoming flashed based failures may be planarization of the previous layer and subsequent redeposition. In variations of these embodiments planarization of the deposit could occur without performing additional deposits while in other variations additional material may be deposited (e.g. via a blanket deposit) if there is a planarizing without a shielding material might result in tearing off relatively large chunks of the first material and getting them inadvertently embedded into the lower layer (i.e. the previous layer).

Another possible build defect is inadequate layer thickness. This defect may result from various causes one of which is shorting and another of which is non-uniform deposition (e.g. some layer portions have reasonably uniform excess thickness while others have reasonably uniform but too little thickness). Inadequate layer thickness may be detected by physical inspection or measurement. If it results from shorting, it may be detected by monitoring deposition voltage as explained in the '494 application. Shorting may be more of a problem associated with use of contact masks as opposed to adhered masks and more specifically with contact masks use an anode as a support.

Inadequate layer thickness may be ascertained by making an absolute measurement of the thickness of the partially formed structure relative to its substrate or by a relative measurement of profile (e.g. using a profilometer). Some measurements may be made by dragging a probe across a surface or by contacting discrete points. In the case of using an adhered mask it may be possible to make measurements without removing the masking material. This may also be possible in some embodiments where anodeless contact masks are used. In some embodiments detection may be made optically, e.g. by focusing an image at two height levels where a translation or required focusing change may be correlated to a height differential.

In other embodiments detection of thin layers may be done on a single-point basis or a multi-point basis where various portions of the layer are checked. In particular when doing single-point or multi-point checking, the target locations may selected based on prior knowledge of regions of the layer that are susceptible to under-plating (e.g. such as very small areas).

In some embodiments indirect techniques may be used to detect inadequate layer thickness. For example, a blanket deposition of a desired thickness may be used and then a planarization operation used. After the planarization operation, the first deposited material should be visible in the desired pattern if it is not, it may be concluded that the deposition was not thickness enough. The pattern recognition may be performed manually or automatically by comparing images obtained by scanning to images generated from cross-sectional data and the like. Any detected differences may result in rejection of the layer or alternatively they may be flagged as problem areas that will require manual inspection and approval prior to continuing with build operations Contrast difference is the difficulty in automatic and manual comparison operations. Contrast can be enhanced but selectively etching one of the materials but it may not lead to desired surface finish and may result in a need to perform additional planarization or polishing operations.

Reworking layers having deposits of inadequate thickness may be performed in different ways. The offending layer may be completely removed (e.g. by planarizing or etching) and then it may be reformed. The layer may be planarized down until a thickness is reached that has the appropriate materials and patterns. If the planing results in a layer thickness that is only slightly less than that desired or if the accuracy between the boundary of the present layer and the next layer is not that critical, it may be possible simply form the next layer using a slightly enhanced thickness of the layer and less than the intended thickness. In other embodiments, the missing thickness of the layer may be made up for by forming a thin layer having the same patterning as that of the just formed layer (i.e. the layer that had inadequate thickness that is too thin).

Smearing is a phenomenon that may occur when planarizing a layer having more than one material and particularly when those materials have a significantly different hardness. The detection of smear can occur by visually comparing an intended materials pattern with a detected pattern. Smearing may manifests itself in two ways: (1) it may shift a boundary position between two materials or (2) it may make the edge go from regular to irregular. In some embodiments, the detection of smear may occur by comparing detected visual images at first and second planarization levels when both levels are within the height of effective deposition of all materials. If boundary positions change, the changes may be the result of the removal or creation of smear or that the deposition height wasn't what was expected. If additional planing is necessary to remove smear, layer height correction methods as discussed above for correcting inadequate layer height may be used. Smear may also be removed or at least reduced by converting from harsh planarization operations to softer planarization operations or even to polishing operations. Smear may also be reduced by use of relatively mild etching operations of either the chemical or electrochemical type that may selective attack the smeared material or that may attack both materials somewhat uniformly.

In other embodiments, smear may be detected by imagining the etches of a selective deposition prior to deposition of a second or subsequent materials and comparing those edges to edges obtained after deposition of the additional material or materials and after planarization. Differences between the images should yield smear based errors or failures. In some embodiments the first image may be taken when the deposition height is not yet completed but is believed to be reasonably close to the desired layer thickness.

Voids and Inclusions are another possible build process failure or problem. One of the sources of voids is bubbles of air or hydrogen that gets introduced in a deposit. Surface voids can be detected visually during or after planarization and buried voids may be detected via x-ray imaging. In some embodiments, variations in plating voltage may be useful in detecting or at least hinting at the presence of significant voids (e.g. due to reduced cathode area). In some embodiments, if voids are found in only one of the materials prior to planarization reaching trimming the deposit to the layer thickness, a blanket deposition (or even a selective deposition) of the effected material may be used to fill the void after which additional planarization may trim the deposit down to the desired layer thickness. If a void exists in more than one material, and the planarization operation has not brought the thickness of deposit down to the layer thickness level, a selective plating operation (e.g. using a mask similar to the original mask used on the layer) may be used to fill the voids in one material and then a blanket or selective deposition may be used to fill the void in the another material. The depositions would be followed by further planarization. If the planarization operation has already brought the deposit thickness down to the layer level, the above noted techniques may be used to fill the voids wherein a choice to work with a slightly thinner than desired layer may be necessary or the depositions may need to build up the thickness sufficiently so that any tolerance in planarization will not result in the wrong materials being located at some locations on the layer.

Of course in other embodiments it may be appropriate to remove the entire layer and reapply it, particularly if structural strength is critical and there is fear that a significant number of voids may exist and may weaken the structure.

In still further embodiments, if the void or voids in a given material on the bounding surface of one layer are determined to be overlaid by the same material on the next layer, it may be appropriate to conclude that the existence of the void or voids are irrelevant since they would automatically be taken care of by depositions made in association with the next layer.

Inclusions may result from abrasives that is used in planarization, nodules from irregular plating, or from contaminant in the plating baths. Detection of inclusions may be done via manual or automatic visual inspection along with manual or automatic comparison to an anticipated image. Detection may occur via x-rays inspection or x-ray tomography. Other embodiments may make use of probes that measure localized conductivity, capacitance, eddy currents, magnetic permeability. In still other embodiments, protruding inclusions may be detected via profilometry, interferometry, or confocal microscopy

As with voids, if an inclusion is going to be trapped within the structural material (e.g. because the next layer is going to overlie it) and the presence of the inclusion can be tolerated from a materials property point of view, then these subsurface inclusions can be ignored. If the inclusion is in the sacrificial material and it's not in contact with any structural material so that it will float off when it is released, it may be possible to again ignore the existence of the inclusion. If an inclusion were located within a small passage where it might get stuck or other problematic area, it may be necessary to trim down the layer to remove it. The trimming down may remove the entire layer or it may remove only a portion of the layer where further layer build up or extension of the thickness of the next layer thickness will be used to address the overall structural height issue.

In some embodiments inclusions may take the form of masking material that has broken off the mask when the mask was being removed or separated from the deposit. In some circumstances these inclusions may not be problematic even though they are dielectric. If they are small enough, are not located in regions outside the structure where they can stuck or where they, and are not located in regions that extend between structural and non-structural material, it is possible that they can be deposited over (e.g. via mushrooming of depositions) and simply trapped within the structural material permanently or within the sacrificial material until release occurs.

In some embodiments the inclusions may be removed by dissolving or the like and then processes similar to those discussed above in association with handling voids may be used to address the problem.

Porosity is similar to voids but different in that it is not concerned with specific voids but a generalized lack of density. Detection of porosity may occur via visual inspection or via surface measurement. In other embodiments porosity detection may occur via x-rays. In still other embodiments porosity detection may be made via deviation from an expected weight. In still other embodiments, x-ray images between an Nth layer and an (N+1)th layer may be compared to help ascertain whether porosity exists in the (N+1)th layer versus a previously formed layer. In some embodiments a conductivity measurement may be made to determine porosity or perhaps a conductivity comparison between successive layers could be used.

In still other embodiments an ultrasonic probe may be used to find voids and/or porosity and/or possibly inclusions. In these ultrasonic probe embodiment may operate with the partially formed structure in water (or other liquid) to improve the conduction of sonic vibrations. In still other embodiments dye penetrant inspection may be used to identify porosity or cracks and the like. In still other embodiments, magnetic permeability variations or eddy current detection may be used to identify porosity or cracks and the like. In still other embodiments vacuum or pressure may be used to draw or push a fluid through a connected series of pore. In still other embodiments, a micro etch may be used to remove smear (of structural material into small adjoining voids that might prevent detecting of the porosity.

Once porosity is detected it may be removed by removing the entire layer of the deposited portion of the layer and then allowing redeposit to occur (hopefully under more favorable conditions)

Some additional examples of potential problems are set forth in FIG. 9A. These additional examples are believed be largely self explanatory and thus only a cursory description of some of them will be given below. These additional problems include (1) deposition of the wrong material, (2) geometary distortion due to stress or other build process failures or due to the inadvertent use of inappropriate data or a mask in defining the deposition region; (3) adhesion failure or weakness between a previously deposited layer and a subsequently deposited layer which may result from, for example, inadequate removal of oxides from the surface of the previously formed layer; (4) electrical conductive failure between layers which may result, for example, from inadequate removal of oxides from the surface of the previously formed layer; (5) non-uniformity of layer thickness which may result from deposition irregularities, failure to control planarity during planarization operations; (6) mechanical properties out of specification which may result from a variety of problems, such as plating bath problems, inappropriate current control during plating, and the like; (7) electrical properties out of specification which may result from a variety of causes; (8) mis-registration of Between Layers which may result from inaccuracies in applying masking material to previously formed layers in preparation for forming subsequent layers; (9) sidewall roughness/non-vertical side walls which may result from lack of coherence in exposing masking material, improper development of masking material, and the like; (10) missing features in a 1^{st} deposited material which may result from improper development of masking material, inability to deposit material into small openings in a masking material, and the like; (11) missing features in a 2^{nd} or subsequently deposited material which may result from inability to reliably remove small pockets of masking material from a first deposited material or the like; (12) poor quality deposition which may result form use of impropriate plating parameters or plating material baths, or the like; (13) cracks in a first deposited material which may result from temperature cycling or other causes, (14) cracks in a second or subsequently deposited material which may result from temperature cycling or other causes; (15) layer thickness error which may result from insufficient, excess, or simply non-parallel planes of planarization of between a current layer and previous layers, (16) accumulated layer thickness error which may result, for example, from measuring height growth of a device layer-to-layer as opposed to measuring from a fixed reference level, and (17) errors found during or after release of a structural material from a sacrificial material which may result from a failure to detect the error during layer-by-layer build up.

FIG. 9B sets forth numerous example remediation actions that may be used in response to the build problems set forth in FIG. 9A as well as other build problems that may be recognized. Some of these remedial actions may be better suited to solving some problems than others and in some situations combining various remedial actions may be appropriate.

The first remedial action includes the thickening of the deposited material on a layer, block 602. This action is particularly suited to addressing inadequate layer thickness, block 504, and possibly layer thickness non-uniformity, block 526.

The second remedial action includes the removal of the current layer (e.g. planarize back to the boundary of the prior layer) and then redeposit it, block 604. This action is particularly suited to addressing voids and inclusions in deposited materials, block 508: porosity problems with depositions, block 512; deposition of the wrong material or materials, block 514; distortion of geometric features in the just deposited layer or partial layer, block 516; failure in adhesion between the just deposited layer or partial layer and a previously deposited layer, block 522; failure in conductivity through the layer, block 524; a mechanical or electrical property being out of specification, blocks 528 and 530; when the just deposited layer or portion of a layer is found to be out of registration (i.e. X & Y positioning of material on two consecutive layers does not provide the intended geometric relationship, block 534; missing features in a first deposition material on the layer or in a subsequently deposited material on that layer, blocks 538 and 542; poor quality deposition of one or more materials on a layer, block 544; and cracks in a first or subsequently deposited material on a layer, blocks 546 and 548. This remediation technique is also applicable to some of the other problems listed in FIG. 9A but other techniques may be more efficient in remedying the problems

The third remedial action includes the removal of the current layer plus δ of the prior layer then redeposition of the current layer such that it extends δ into the prior layer, block 606. This action is particularly suited to addressing problems noted above in association with the second remedial action particular where the removed layer has regions of structural material that overlay regions of sacrificial material on the previous layer so that it is ensured that all deposited material from the current layer is adequately removed or when a deposition of the wrongly deposited material is to occur.

The fourth remedial action includes the removal of a portion of the current layer and then redeposition of that portion, block 608. This action is particularly suited to addressing excess smearing problems, block 506; layer thickness non-uniformity problems, block 526; and potentially when and cracks in a first or subsequently deposited material on a layer occur, blocks 546 and 548. This remedial action minimizes the time spent on rework while remove imperfections or flaws that primarily exist on the exposure (e.g. upper surface) of the last deposited layer.

The fifth remedial action includes the removal of a portion of the current layer and then deposition of the next layer such that it attains a thickness equal to its intended thickness plus the overlap into the current layer, block 612. This action is particularly suited to addressing smearing problems, block 506; layer thickness non-uniformity problems, block 526; and potentially when and cracks in a first or subsequently deposited material on a layer occur, blocks 546 and 548. This remedial action allow problems to be corrected that exist only near the surface of a deposited layer where slight vertical inaccuracy in placement of the next layer (e.g. the bottom portion of the law assuming the layers are being stacked vertically) or in the thickness of the next layer is tolerable where time is saved by not having to remask and redeposit a thin incremental amount on a substantially formed layer.

The sixth remedial action includes the removal of multiple layers of material and the redeposition of them, block 616. This action is particularly suited to addressing some of the same problems noted above for the second remedial action but more particularly when the error to be corrected extends down into several layers, or when several layers must be removed and reformed as a result of overall yield dropping below a cutoff level which requires multi-layer reworking as opposed to scrapping the partial build and starting over.

The seventh remedial action includes the performance of a shallow or micro-etch of a selected material, block 618 while the eighth remedial action includes the performance of a shallow or micro- etch of all materials, block 622. These action in combination with the second remedial action are particularly suited to addressing adhesion failure problems, block 522. These remedial actions may be converted into anticipatory actions where it is believed that adhesion failure is likely. These remedial actions may also aid in establishing higher optical contrast that may be useful in the process of visually inspecting layers or partially formed layers

The ninth remedial action includes the performance of a shallow etch back, after selective deposition and prior to a second deposition, block 624. This action is particularly suited to addressing flash problems, block 502.

The tenth remedial action includes the removal of a portion of an entire layer or the entire layer plus part of another layer based on an analysis of critical layers or features and/or non-critical layers or features and then redepositing the removed material such as to optimize critical features or at least not to negatively impact critical features, block 632. This action is particularly suited to addressing layer thickness error problems, block 552 and accumulated error problems, block 554, particularly when selected layer levels (levels on which critical features are to exist) need to be more precisely located than normal layer leveling procedures allow.

The eleventh remedial action includes the release of a structure, examination of its features, then re-embedding the structure in a suitable material (so that planarization can occur with minimal concerning of chipping or otherwise damaging edges of the structural material at the planarization level, block 636.

The twelfth remedial action includes a physical label or creation of a data log of specific dies that are considered to have failed based on the recognized problem, block 638. This action is particularly suited to the batch formation of devices where problems have occurred on only a small portion of the devices, and it is preferable to continue building and to take the yield loss as opposed to slowing the build process in an attempt to raise yield level. Of course if subsequent formation operations result in failure of additional die (as opposed to the same die) a point may be reached where yield loss is considered excessive, and removal of one or more layers of material may be necessitated to bring yield back to a desired level.

As with the first remedial action, the other remedial actions are particularly suited to the problems noted above but they may also have applicability to greater or lesser extents to the other problems noted in FIG. 9A. Furthermore, in some embodiments, specific remedial actions may be combined with other remedial actions, or they may be implemented in a changing series starting with the most convenient remediation approach followed by one or more less convenient, but possibly more effective, remediation techniques if the problem isn't alleviated in a first or subsequent attempt.

Some embodiments may employ diffusion bonding or the like to enhance adhesion between successive layers of material. Various teachings concerning the use of diffusion bonding in electrochemical fabrication process is set forth in U.S. patent application Ser. No. 60/534,204 which was filed Dec. 31, 2003 by Cohen et al. which is entitled “Method for Fabricating Three-Dimensional Structures Including Surface Treatment of a First Material in Preparation for Deposition of a Second Material” and which is hereby incorporated herein by reference as if set forth in full.

Teachings concerning the formation of structures on dielectric substrates and/or the formation of structures that incorporate dielectric materials into the formation process and possibility into the final structures as formed are set forth in a number of patent applications filed on Dec. 31, 2003. The first of these filings is U.S. patent application Ser. No. 60/534,184, which is entitled “Electrochemical Fabrication Methods Incorporating Dielectric Materials and/or Using Dielectric Substrates”. The second of these filings is U.S. patent application Ser. No. 60/533,932, which is entitled “Electrochemical Fabrication Methods Using Dielectric Substrates”. The third of these filings is U.S. patent application Ser. No. 60/534,157, which is entitled “Electrochemical Fabrication Methods Incorporating Dielectric Materials”. The fourth of these filings is U.S. patent application Ser. No. 60/533,891, which is entitled “Methods for Electrochemically Fabricating Structures Incorporating Dielectric Sheets and/or Seed layers That Are Partially Removed Via Planarization”. A fifth such filing is U.S. patent application Ser. No. 60/533,895, which is entitled “Electrochemical Fabrication Method for Producing Multi-layer Three-Dimensional Structures on a Porous Dielectric”. These patent filings are each hereby incorporated herein by reference as if set forth in full herein.

The patent applications and patents set forth below are hereby incorporated by reference herein as if set forth in full. The teachings in these incorporated applications can be combined with the teachings of the instant application in many ways: For example, enhanced methods of producing structures may be derived from some combinations of teachings, enhanced structures may be obtainable, enhanced apparatus may be derived, and the like.

| US Pat App No, Filing Date | |
|---|---|
| US App Pub No, Pub Date | Inventor, Title |
| 09/493,496 - Jan. 28, 2000 | Cohen, “Method For Electrochemical Fabrication” |
| 10/677,556 - Oct. 1, 2003 | Cohen, “Monolithic Structures Including Alignment |
| | and/or Retention Fixtures for Accepting Components” |
| 10/830,262 - Apr. 21, 2004 | Cohen, “Methods of Reducing Interlayer |
| | Discontinuities in Electrochemically Fabricated Three- |
| | Dimensional Structures” |
| 10/271,574 - Oct. 15, 2002 | Cohen, “Methods of and Apparatus for Making High |
| 2003-0127336A - Jul. 10, 2003 | Aspect Ratio Microelectromechanical Structures” |
| 10/697,597 - Dec. 20, 2002 | Lockard, “EFAB Methods and Apparatus Including |
| | Spray Metal or Powder Coating Processes” |
| 10/677,498 - Oct. 1, 2003 | Cohen, “Multi-cell Masks and Methods and Apparatus |
| | for Using Such Masks To Form Three-Dimensional |
| | Structures” |
| 10/724,513 - Nov. 26, 2003 | Cohen, “Non-Conformable Masks and Methods and |
| | Apparatus for Forming Three-Dimensional Structures” |
| 10/607,931 - Jun. 27, 2003 | Brown, “Miniature RF and Microwave Components and |
| | Methods for Fabricating Such Components” |
| 10/841,100 - May 7, 2004 | Cohen, “Electrochemical Fabrication Methods |
| | Including Use of Surface Treatments to Reduce |
| | Overplating and/or Planarization During Formation of |
| | Multi-layer Three-Dimensional Structures” |
| 10/387,958 - Mar. 13, 2003 | Cohen, “Electrochemical Fabrication Method and |
| 2003-022168A - Dec. 4, 2003 | Application for Producing Three-Dimensional |
| | Structures Having Improved Surface Finish” |
| 10/434,494 - May 7, 2003 | Zhang, “Methods and Apparatus for Monitoring |
| 2004-0000489A - Jan. 1, 2004 | Deposition Quality During Conformable Contact Mask |
| | Plating Operations” |
| 10/434,289 - May 7, 2003 | Zhang, “Conformable Contact Masking Methods and |
| 20040065555A - Apr. 8, 2004 | Apparatus Utilizing In Situ Cathodic Activation of a |
| | Substrate” |
| 10/434,294 - May 7, 2003 | Zhang, “Electrochemical Fabrication Methods With |
| 2004-0065550A - Apr. 8, 2004 | Enhanced Post Deposition Processing Enhanced Post |
| | Deposition Processing” |
| 10/434,295 - May 7, 2003 | Cohen, “Method of and Apparatus for Forming Three- |
| 2004-0004001A - Jan. 8, 2004 | Dimensional Structures Integral With Semiconductor |
| | Based Circuitry” |
| 10/434,315 - May 7, 2003 | Bang, “Methods of and Apparatus for Molding |
| 2003-0234179 A - Dec. 25, 2003 | Structures Using Sacrificial Metal Patterns” |
| 10/434,103 - May 7, 2004 | Cohen, “Electrochemically Fabricated Hermetically |
| 2004-0020782A - Feb. 5, 2004 | Sealed Microstructures and Methods of and Apparatus |
| | for Producing Such Structures” |
| 10/841,006 - May 7, 2004 | Thompson, “Electrochemically Fabricated Structures |
| | Having Dielectric or Active Bases and Methods of and |
| | Apparatus for Producing Such Structures” |
| 10/434,519 - May 7, 2003 | Smalley, “Methods of and Apparatus for |
| 2004-0007470A - Jan. 15, 2004 | Electrochemically Fabricating Structures Via Interlaced |
| | Layers or Via Selective Etching and Filling of Voids” |
| 10/724,515 - Nov. 26, 2003 | Cohen, “Method for Electrochemically Forming |
| | Structures Including Non-Parallel Mating of Contact |
| | Masks and Substrates” |
| 10/841,300 - May 7, 2004 | Lockard, “Methods for Electrochemically Fabricating |
| | Structures Using Adhered Masks, Incorporating |
| | Dielectric Sheets, and/or Seed layers That Are |
| | Partially Removed Via Planarization” |
| 10/841,347 - May 7, 2004 | Cohen, “Multi-step Release Method for |
| | Electrochemically Fabricated Structures” |

Various other embodiments of the present invention exist. Some of these embodiments may be based on a combination of the teachings herein with various teachings incorporated herein by reference. Some embodiments may not use any blanket deposition process and/or they may not use a planarization process. Some embodiments may involve the selective deposition of a plurality of different materials on a single layer or on different layers. Some embodiments may use blanket or selective depositions processes that are not electrodeposition processes. Some embodiments may use conformable contact masks, non-conformable masks, proximity masks, and/or adhered masks for selective patterning operations. Some embodiments may use nickel as a structural material while other embodiments may use different materials such as gold, silver, or any other electrodepositable materials that can be separated from the selected sacrificial material (e.g. copper and/or some other sacrificial material). Some embodiments may use copper as the structural material with or without a sacrificial material. Some embodiments may remove a sacrificial material while other embodiments may not. In some embodiments, the depth of deposition may be enhanced by pulling the conformable contact mask away from the substrate as deposition is occurring in a manner that allows the seal between the conformable portion of the CC mask and the substrate to shift from the face of the conformal material to the inside edges of the conformable material.

In some embodiments, monitoring of build problems may occur via automated detection systems. For example, voltage monitoring or current monitoring during plating; resistance testing, performance of various mechanical tests, such as impact testing; automatic or manual visual inspection with or without comparison targets, and the like. Other tests will be apparent to those of skill in the art.

In view of the teachings herein, many further embodiments, alternatives in design and uses of the instant invention will be apparent to those of skill in the art. As such, it is not intended that the invention be limited to the particular illustrative embodiments, alternatives, and uses described above but instead that it be solely limited by the claims presented hereafter.

1. An electrochemical fabrication process for producing a three-dimensional structure from a plurality of adhered layers, the process comprising:
(A) selectively depositing at least a portion of a layer onto the substrate, wherein the substrate may comprise previously deposited material;
(B) forming a plurality of layers such that successive layers are formed adjacent to and adhered to previously deposited layers, wherein said forming comprises repeating operation (A) a plurality of times;
wherein at least a plurality of the selective depositing operations comprise:
(1) adhering a mask to or locating a preformed mask in contact with or in proximity to a substrate;
(2) in presence of a plating solution, conducting an electric current between an anode and the substrate through the at least one opening in the mask, such that a selected deposition material is deposited onto the substrate to form at least a portion of a layer; and
(3) removing the mask from the substrate;
wherein during one or more layer formation processes or after one or more layer formation processes at least one inspection occurs that is capable of identifying a plurality of process failures and wherein at least one of any failures is correlated to a potential corrective action and at least one corrective action is taken to allow successful fabrication of the structure to continue.

2. The process of claim 1, wherein a plurality of layers comprise at least one structural material and at least one sacrificial material.

3. The process of claim 1 wherein, based at least in part on the identified failure, a conclusion is reached that the deposition for a given layer is not acceptable, wherein the process additionally comprises:
(A) removing at least a portion of the material deposited in association with the given layer; and
(B) repeating the deposition for at least a portion of the given layer.

4. The process of claim 3 wherein the conclusion is, at least in part based on a visual inspection of the resulting deposit for the given layer.

5. An electrochemical fabrication process for producing a three-dimensional structure from a plurality of adhered layers, the process comprising:
(A) selectively depositing at least a portion of a layer onto the substrate, wherein the substrate may comprise previously deposited material;
(B) forming a plurality of layers such that successive layers are formed adjacent to and adhered to previously deposited layers, wherein said forming comprises repeating operation (A) a plurality of times;
wherein at least a plurality of the selective depositing operations comprise:
(1) adhering a mask to or locating a preformed mask in contact with or in proximity to a substrate;
(2) in presence of a plating solution, conducting an electric current between an anode and the substrate through the at least one opening in the mask, such that a selected deposition material is deposited onto the substrate to form at least a portion of a layer; and
(3) removing the mask from the substrate;
wherein during, or after, formation of a given layer, the layer is inspected or formation parameters are compared to anticipated parameter values such that a determination concerning the existence of a plurality of potential build problems is made wherein if it is determined that the layer was not formed correctly, at least a portion of material deposited in association with the layer is removed and replacement material is deposited.

6. The process of claim 5, wherein a plurality of layers comprise at least one structural material and at least one sacrificial material.

7. The process of claim 5 wherein the inspection comprises monitoring an electrical characteristic of a selective deposition operation.

8. The process of claim 7 wherein the electrical characteristic comprises a voltage between the anode and the cathode during conduction of the electric current.

9. The process of claim 7 wherein the monitoring occurs during formation of substantially all layers of the plurality.

10. The process of claims 8 wherein a monitored voltage for each layer comprises a measurement of a voltage profile over deposition time for each layer.

11. The process of claim 10 wherein at least two points of the measured voltage profile for a given layer are used in making a comparison to an anticipated voltage profile, and based at least in part on the result of the comparison, a conclusion is reached as to whether or not the deposition was acceptable.

12. The process of claim 5 wherein the formation of each of a number of layers comprise at least one blanket deposition as well as the selective deposition wherein for a given layer the selectively deposited material is different from a material deposited by blanket deposition.

13. The process of claim 5 wherein the plurality of selective depositions comprise the deposition of a plurality of different materials.

14. The process of claim 5 wherein at least a portion of one layer is formed by a non-electroplating deposition process.

15. The process of claim 5 wherein a plurality of depositions occur during the formation of each of a number of layers wherein at least one of the depositions on each of the number of layers deposits copper and at least one of the other depositions on the number of layers deposits nickel.

16. The process of claim 5 wherein the selective depositing for each of a number of layers comprises at least two selective depositions.

17. The process of claim 5 wherein a number of the plurality of layers are each formed by depositing at least one structural material using at least one deposition and by depositing at least one sacrificial material by using at least one other deposition.

18. The process of claim 14 wherein at least a portion of the at least one sacrificial material is removed after formation of a plurality of layers to reveal a three-dimensional structure comprised of at least one structural material.

19. A process for forming a multilayer three-dimensional structure, comprising:
(a) forming and adhering a layer of material to a substrate, wherein the substrate may include previously formed layers;
(b) repeating the forming and adhering operation of (a) a plurality of times to build up a three-dimensional structure from a plurality of adhered layers;
wherein the formation of each of at least a plurality of layers, comprises:
(1) obtaining a selective pattern of deposition of a first material having voids, comprising at least one of:
(a) selectively depositing a first material onto the substrate such that at least one void remains, wherein the depositing comprises:
(i) adhering a mask and a surface of the substrate together or bringing a preformed mask into contact with or in proximity to the substrate in preparation for depositing a first material;
(ii) depositing the first material onto the substrate with the mask in place;
(iii) separating the mask and the substrate to expose the at least one void; or
(b) depositing a first material onto the substrate and selectively etching the deposit of the first material to form voids therein, wherein the etching comprises:
(i) adhering a mask and a surface of the deposited first material together or bring a preformed mask into contact with or in proximity to the substrate;
(ii) etching, with the mask in place, into the first material to form at least one void;
(iii) separating the mask and the substrate; and
(2) depositing a second material into the at least one void, and
wherein during, or after, formation of a given layer, the layer is inspected, or formation parameters are compared to anticipated parameter values, such that if it is determined that the layer was not formed correctly, at least a portion of material deposited in association with the layer is removed and replacement material is deposited.

20. The process of claim 19 wherein at least one of the first or second deposited materials undergoes a planarization operation at least once during the formation of each of a plurality of layers.

21. The process of claim 19 wherein the layer inspection uncovers at least one of the problems set forth in FIG. 9A.

22. The process of claim 19 wherein the removal of at least a portion of the material deposited in association with the layer is removed and replacement material is deposited comprises at least one of the actions set forth in FIG. 9B.

23. An electrochemical fabrication process for producing a three-dimensional structure from a plurality of adhered layers, the process comprising:
(A) selectively depositing at least a portion of a layer onto the substrate, wherein the substrate may comprise previously deposited material;
(B) forming a plurality of layers such that successive layers are formed adjacent to and adhered to previously deposited layers, wherein said forming comprises repeating operation (A) a plurality of times;
wherein at least a plurality of the selective depositing operations comprise:
(1) adhering a mask to or locating a preformed mask in contact with or in proximity to a substrate;
(2) depositing onto the substrate a desired material to form at least a portion of a layer; and
(3) removing the mask from the substrate;
wherein during one or more layer formation processes or after one or more layer formation processes at least one inspection occurs, or formation parameters are compared to anticipated parameter values, that is capable of identifying a plurality of process failures and wherein at least one of any failures is correlated to a potential corrective action and at least one corrective action is taken to allow successful fabrication of the structure to continue.

24. The process of claim 23 wherein the desired material undergoes a planarization operation at least once during the formation of each of a plurality of layers.

25. The process of claim 23 wherein the inspection or comparison uncovers at least one of the problems set forth in FIG. 9A.

26. The process of claim 23 wherein the corrective action comprises at least one of the corrective actions set forth in FIG. 9B.

27. An electrochemical fabrication process for producing a three-dimensional structure from a plurality of adhered layers, the process comprising:
(A) selectively depositing at least a portion of a layer onto the substrate, wherein the substrate may comprise previously deposited material;
(B) forming a plurality of layers such that successive layers are formed adjacent to and adhered to previously deposited layers, wherein said forming comprises repeating operation (A) a plurality of times;
wherein at least a plurality of the selective depositing operations comprise:
(1) adhering a mask to or locating a preformed mask in contact with or in proximity to a substrate;
(2) depositing onto the substrate a desired material to form at least a portion of a layer; and
(3) removing the mask from the substrate;
wherein during, or after, formation of a given layer, the layer is inspected or formation parameters are compared to anticipated parameter values such that a determination concerning the existence of a plurality of potential build problems is made wherein if it is determined that the layer was not formed correctly, at least a portion of material deposited in association with the layer is removed and replacement material is deposited.

28. The process of claim 27 wherein the desired material undergoes a planarization operation at least once during the formation of each of a plurality of layers.

29. The process of claim 27 wherein the inspection or comparison uncovers at least one of the problems set forth in FIG. 9A.

30. The process of claim 27 wherein the removal and replacement of material comprises at least one of the corrective actions set forth in FIG. 9B.
